(19) United States
(12) Patent Application Publication
(10) Pub. No.: US 2024/0420901 A1
(43) Pub. Date: Dec. 19, 2024

(54) PRESSURE MODULE

(71) Applicants: Peratech Holdco Limited, Catterick Garrison, North Yorkshire (GB); PERA ELECTRONIC TECHNOLOGY (SUZHOU) CO. LTD, Jiansu (CN)

(72) Inventors: Zhang WEN, Jiansu (CN); Xu FENG, Jiansu (CN); Wei XIN, Jiansu (CN); Cao JIN, Jiansu (CN); You DAWEI, Jiansu (CN); Lv BING, Jiansu (CN); Li ZEFENG, Jiansu (CN); Wang SHICHAO, Jiansu (CN)

(21) Appl. No.: 18/703,179

(22) PCT Filed: Oct. 19, 2022
(86) PCT No.: PCT/GB2022/000083

§ 371 Date: Apr. 19, 2024

(30) Foreign Application Priority Data
Oct. 19, 2021 (CN) 202122517981.5

(51) Int. Cl. H01H 13/14; H01H 13/79

(52) U.S. Cl. CPC H01H 13/14; H01H 13/79; H01H 2201/036; H01H 2207/026; H01H 2209/074

(57) ABSTRACT

A pressure module comprises a substrate, a support structure and a pressing membrane. The support structure is connected to the substrate and the pressing membrane to form an accommodating cavity between the substrate and the pressing membrane. An electrode is disposed on a surface of the substrate or the pressing membrane and a variable resistance layer is respectively disposed on the opposite surface of the other of the substrate and the pressing membrane. On application of pressure to the pressing membrane, the pressing membrane is elastically deformed and the variable resistance layer is brought into contact with the electrode to form a contact area and a resistance value between the variable resistance layer and the electrode. The contact area and the elastic deformation is positively correlated.

### CROSS REFERENCE TO RELATED APPLICATIONS

This application claims priority from Chinese Utility Model number 202122517981.5, filed on 19 Oct. 2021, the whole contents of which are incorporated herein by reference.

### TECHNICAL FIELD

The present invention relates to a pressure module and a pressing structure thereof, and a keyboard or pressure sensor comprising such a pressure module.

### BACKGROUND OF THE INVENTION

Existing membrane electronic keyboards typically comprise a plurality of keys which provide input devices for a user. In such keyboards, each key comprises a key cap, a domed silicone elastomer and a plurality of films including an upper film and a lower film onto which a conductive coating is printed thereon.

However, the arrangement means that this type of keyboard can usually only obtain two states of pressing and releasing, which limits the usage requirements for different key functions according to different pressing forces of the user.

The present application aims to provide a pressure module and a pressing structure thereof to solve the above problems.

### BRIEF SUMMARY OF THE INVENTION

According to a first aspect of the present invention, there is provided a pressure module comprising: a substrate; a support structure; and a pressing membrane; wherein said support structure is connected to said substrate and said pressing membrane to form an accommodating cavity between said substrate and said pressing membrane; and an electrode is disposed on a surface of said substrate or said pressing membrane and a variable resistance layer is respectively disposed on the opposite surface of said other of said substrate and said pressing membrane; wherein on application of pressure to said pressing membrane, said pressing membrane is elastically deformed and said variable resistance layer is brought into contact with said electrode to form a contact area and a resistance value between said variable resistance layer and said electrode; and said contact area and said elastic deformation is positively correlated.

In the pressure module, the support structure connects the substrate and the pressing membrane to form an accommodating cavity between the substrate and the pressing membrane, and the electrode and a variable resistance layer are respectively provided on opposite surfaces of the substrate of the accommodating cavity and the pressing membrane. In this way, after the pressing membrane is elastically deformed by pressure, the electrode and the variable resistance layer are brought into contact to form a contact area and the variable resistance layer is squeezed such that the squeezed variable resistance layer is converted from an insulator to a conductor so that the electrode and the variable resistance layer form an electrical path.

Due to the change of the resistance value of the variable resistance layer, the degree of pressure and the change of the contact area, controllable adjustment of the pressing module according to the pressure is realized.

In addition, the solution of the present application uses the variable resistance layer itself as an electrode, thereby making the pressing module simple in structure and saving costs.

In an optional embodiment of the first aspect, the contact area is inversely related to the resistance value between the variable resistance layer and the electrode.

In an optional embodiment of the first aspect, the electrode is disposed on a surface of the pressing membrane, and the variable resistance layer is disposed on the opposite surface of the substrate.

In an optional embodiment of the first aspect, the electrode is disposed on a surface of the substrate, and the variable resistance layer is disposed on an opposite surface of the pressing membrane.

In an optional embodiment of the first aspect, one of the electrode and the variable resistance layer comprises a substantially solid circular-shaped coating.

In an embodiment of the first aspect, the other of the electrode and the variable resistance layer comprises a coating comprising a plurality of interdigitated fingers.

In an optional embodiment of the first aspect, the other of the electrode and the variable resistance layer also comprises a substantially solid circular-shaped coating.

In an optional implementation of the first aspect, the substantially solid circular-shaped coating includes a signal bus, one end of the signal bus is bent to form a circle, and the electrode and the variable resistance layer are coated in the circle.

In an optional implementation of the first aspect, the coating comprising a plurality of interdigitated fingers includes a signal bus, one end of the signal line is bent to form two opposite half-arcs, and each half-arc extends towards the opposite half-arc; further comprising a plurality of signal branch lines, the plurality of signal branch lines of the two opposite half-arcs are arranged alternately in sequence.

According to a second aspect of the present invention, there is provided a keyboard comprising a pressure module. The keyboard provides a pressing structure which includes the pressure module.

In the aforementioned pressing structure, since the pressing structure includes the pressing module, the pressing structure can realize the controllable adjustment of the pressing module according to the pressure.

In addition, the pressing structure is simple in structure and low in cost. In a further embodiment, the pressing structure is provided in the form of a pressure sensor comprising the pressure module.

Embodiments of the invention will be described, by way of example only, with reference to the accompanying drawings. The detailed embodiments show the best mode known to the inventor and provide support for the invention as claimed. However, they are only exemplary and should not be used to interpret or limit the scope of the claims. Their purpose is to provide a teaching to those skilled in the art. Components and processes distinguished by ordinal phrases such as “first” and “second” do not necessarily define an order or ranking of any sort.

### BRIEF DESCRIPTION OF THE SEVERAL VIEWS OF THE DRAWINGS

FIG. 1 shows an electronic device comprising a keyboard comprising a pressure module of the present invention;

FIG. 2 shows a cross-sectional view of a pressure module in an embodiment of the present invention;

FIG. 3 shows a cross-sectional view of a pressure module in a further embodiment of the present invention;

FIG. 4 shows a cross-sectional view of a pressure module in an alternative embodiment of the present invention;

FIGS. 5A and 5B show plan views of the electrode and variable resistance layer of the embodiment of FIG. 4;

FIG. 6 shows a cross-sectional view of a pressure module in a further alternative embodiment of the present invention;

FIG. 7 show plan views of the electrode and variable resistance layer of the embodiment of FIG. 6;

FIG. 8 shows a cross-sectional view of a pressure module in a still further alternative embodiment of the present invention;

FIG. 9 show plan views of the electrode and variable resistance layer of the embodiment of FIG. 8.

### DETAILED DESCRIPTION OF EMBODIMENTS OF THE INVENTION

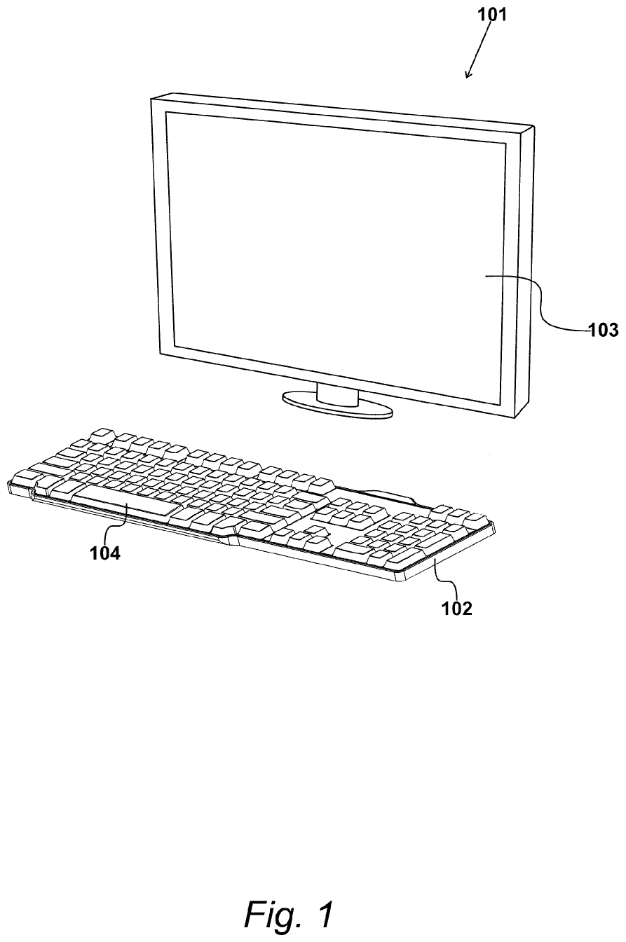

### FIG. 1

An electronic device in the form of a personal computer is shown in FIG. 1. Electronic device 101 comprises a keyboard 102 and a display 103. Keyboard 102 comprises a plurality of keys 104, keyboard 102 providing a pressing structure comprising a pressure module in accordance with any of the embodiments described further herein.

It is appreciated that each key 104 may comprise its own pressure module, however, in an embodiment, a single pressure module is provided to keyboard 102 and is responsive to each key.

In this illustrated embodiment, since the pressing structure includes a pressing module, the pressing structure realizes a function of controllable adjustment of the pressing module according to the pressure. In addition, the pressing structure is simple in structure and low in cost.

In an alternative embodiment, the pressing structure is provided by a pressure sensor, which comprising a corresponding pressure module as described herein. In one embodiment, the pressure sensor and corresponding pressure module is further incorporated into electronic device 101. It is appreciated that a pressing structure comprising the pressure module described herein may be any other suitable device requiring a pressure sensing response.

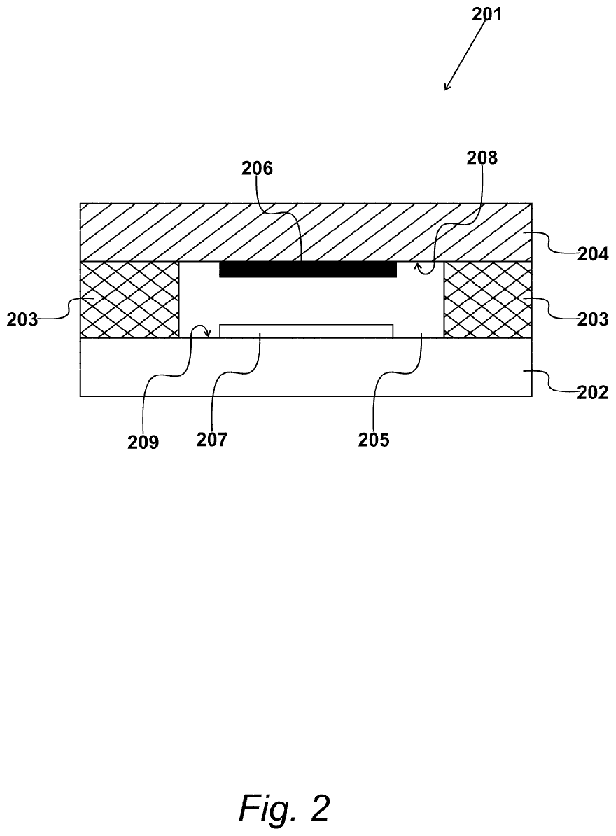

### FIG. 2

An example embodiment of a pressure module which is included in the keyboard or pressure sensor described with respect to FIG. 1 is shown in FIG. 2.

Pressure module 201 comprises a substrate 202, a support structure 203 and a pressing membrane 204. Support structure 203 is connected to and between substrate 202 and pressing membrane 204.

An accommodating cavity 205 is formed between pressing membrane 204, and, within accommodating cavity 205, an electrode 206 and a variable resistance layer 207 are respectively disposed on the surfaces of pressing membrane 204 and substrate 202 opposite to each other. That is, electrode 206 is disposed on a surface 208 of pressing membrane 204 and variable resistance layer 207 is disposed on surface 209 of substrate 202. In this way, the variable resistance layer 207 is opposite the electrode 206.

Further, electrode 206 is disposed on an upper wall of accommodating cavity 205 and variable resistance layer 207 is disposed on a bottom wall of the accommodating cavity 205.

In the embodiment, substrate 202 and pressing membrane 204 comprise an insulating material. For example, the insulating material comprises a material such as polyimide or polyester resin. In an embodiment, the insulating material may be provided in the form of a film.

In the embodiment, electrode 206 comprises a conductive material, which may be any suitable material such as, but not limited to a carbon paste, a silver paste or similar.

In the embodiment, variable resistance layer 207 comprises a coating, and in an embodiment, the variable resistance layer is a polymer. Variable resistance material may comprise any suitable material such as a carbon-based polymer material such as graphene or a quantum tunnelling composite material.

In the embodiment, support structure 203 comprises a viscous substance such as a glue or adhesive which is configured to connect substrate 202 and pressing membrane 204 and form a support. It is appreciated that other such suitable materials may be utilized.

In the embodiment, when pressing membrane 204 is not under pressure or under insufficient pressure, variable resistance layer 207 and electrode 206 are not in contact, and the variable resistance layer 207 is an insulator at this time.

On application of a pressure to pressing membrane 204, pressing membrane 204 is elastically deformed, and the elastically deformed pressing membrane 204 causes the variable resistance layer 207 to contact electrode 206 such that the variable resistance layer 207 is squeezed to produce deformation of the variable resistance layer 207.

After the internal particles of the compressive variable resistance layer 207 are squeezed, the spacing and distribution of the internal particles are changed, so that the variable resistance layer 207 becomes a conductor, thereby forming an electrical path between the variable resistance layer 207 and the electrode 206 thereby forming a resistance.

With different applied pressures on pressing membrane 204, the elastic deformation produced by pressing membrane 204 is accordingly different, such that the deformation of the variable resistance layer 207 and, consequently, the contact area with the electrode 206 are different. These differences make the resistance value of the variable resistance layer 207 to be different for a different applied pressure. In this way, different contact area values result in different output resistance signals, thereby realizing a controllable function adjustment according to the pressure applied.

The contact area of the variable resistance layer 207 with the electrode 206 is positively correlated with the elastic deformation of pressing membrane 204. For example, the greater the elastic deformation of the pressing membrane 204, the narrower the accommodating cavity 205, thereby increasing the contact area between electrode 206 and variable resistance layer 207.

The resistance value of variable resistance layer 207 is inversely related to the contact area and the degree of deformation. For example, the larger the contact area, the smaller the resistance value of the variable resistance layer 207 and the greater the degree of deformation, the smaller the resistance value of the variable resistance layer 207.

Thus, in the pressure module described, when the pressing membrane 204 is elastically deformed by a given pressure, the lower surface of the pressing membrane 204 in accommodating cavity 205 moves downwards, and the downward moving pressing membrane 204 drives the electrode 205 on its lower surface. Electrode 205 therefore also moves downwards, so that electrode 205 is in contact with variable resistance layer 207 on the bottom wall of the accommodating cavity 205, and squeezes the variable resistance layer 207. After the variable resistance layer 207 is squeezed, it is converted from an insulator to a conductor, and then connected to electrode 205. When the pressure on the pressing membrane 204 increases, the pressing force of electrode 205 on the variable resistance layer 207 increases and the contact area with the variable resistance layer 207 also increases, so that the resistance value of the variable resistance layer 207 is reduced, thereby realizing the controllable adjustment of the pressing module according to the pressure.

In the pressing module as described, support structure 203 is designed to connect the substrate 202 and the pressing membrane 204 to form an accommodating cavity 205 which accommodates the deformation of the variable resistance layer upon an application of pressure. In addition, the solution of the present application uses the variable resistance layer itself as an electrode, thereby making the designed pressing module simple in structure and saving costs.

It is appreciated that FIG. 1 describes one pressure module 201 in accordance with the invention. As will now be described herein, alternative pressure modules may also be suitable for use in a similar manner and function in a similar way to the pressure module 201 with the differences as described. Consequently, it is appreciated that the electrodes, pressing membranes, support structures, substrates and variable resistance layers described in the following embodiments are substantially similar as those previously described unless otherwise indicated. Further adaptations not explicitly described but including the features of the embodiments described herein may also fall within the scope of the present invention.

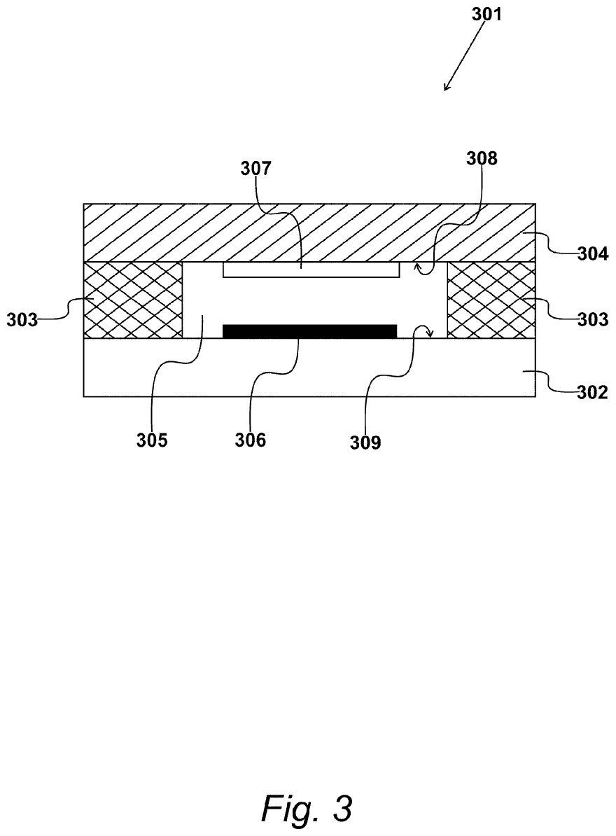

### FIG. 3

An alternative embodiment of a pressure module in accordance with the invention is shown in FIG. 3.

Pressure module 301 comprises a substrate 302, a support structure 303 and a pressing membrane 304. Support structure 303 is connected to and between substrate 302 and pressing membrane 304.

In the embodiment, electrode 306 is disposed on surface 309 of substrate 302, that is, electrode 306 is disposed on a bottom wall of accommodating cavity 305. Variable resistance layer 307 is disposed on surface 308 of pressing membrane 304 on the opposite surface to substrate 302, that is, variable resistance layer 307 is disposed on the upper wall of the accommodating cavity 305.

In the embodiment of pressure module 301, when pressing membrane 304 is elastically deformed by a given pressure, the lower surface of the pressing membrane 304 moves downwards into accommodating cavity 305, and the downward moving pressing membrane 304 drives the lower surface of the pressing membrane 304. The variable resistance layer 307 also moves downward, so that the variable resistance layer 307 is brought into contact with electrode 306 on the bottom wall of the accommodating cavity 305. Variable resistance layer 307 is consequently squeezed, and variable resistance layer 307 is converted from an insulator to a conductor, and then connected to electrode 305.

When the pressure on the pressing membrane 304 increases, the pressing force of electrode 306 on the variable resistance layer 307 increases and the contact area of the variable resistance layer 307 with the electrode 306 is also increased, thereby reducing the resistance value of the variable resistance layer 307, thereby enabling controllable function of the pressing module according to the pressure.

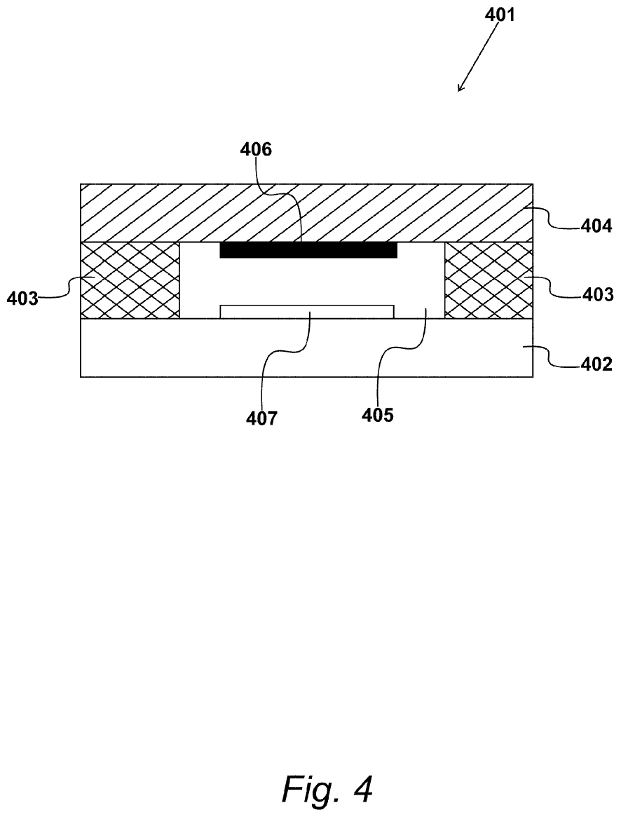

### FIG. 4

A further embodiment of a pressure module in accordance with the invention is shown in FIG. 4.

In the embodiment, pressure module 401 comprises a substrate 402, a support structure 403 and a pressing membrane 404. Support structure 403 is connected to and between substrate 402 and pressing membrane 404.

Pressure module 401 is substantially similar to pressure module 201 in that an accommodating cavity 405 is formed between pressing membrane 404 and substrate 402, and, within accommodating cavity 405, an electrode 406 and a variable resistance layer 407 are respectively disposed on the surfaces of pressing membrane 404 and substrate 402 opposite to each other.

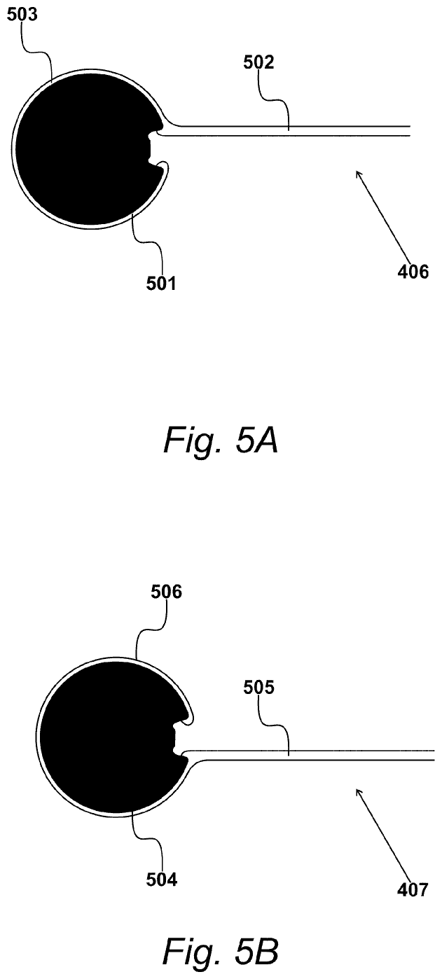

In the embodiment, electrode 406 and variable resistance layer 407 comprise solid circular-shaped coatings, as will be described further with respect to FIGS. 5A and 5B.

### FIG. 5A and FIG. 5B

FIG. 5A illustrates a plan view of electrode 406 and FIG. 5B illustrates a plan view of variable resistance layer 407.

In the embodiment, electrode 406 and variable resistance layer 407 each comprise solid circular-shaped coatings.

Referring first to electrode 406 in FIG. 5A, solid circular-shaped coating 501 comprises a signal bus 502 and one end of the signal bus 502 is formed by bending into a circle 503. In the embodiment, circle 503 is coated with an electrode coating, for example, such as a metallic coating such as one comprising a silver paste or similar, to form electrode 406.

In a similar way, referring to variable resistance layer 407 in FIG. 5B, solid circular-shaped coating 504 comprises a signal bus 505 and one end of the signal bus 505 is formed by bending into a circle 506. In the embodiment, circle 506 is coated with a carbon-based polymer material such as graphene or a quantum tunnelling composite material to form variable resistance layer 407.

In this embodiment, electrode 406 and variable resistance layer 407 are both solid circular-shaped coatings, so that a good contact is formed when electrode 406 and variable resistance layer 407 are brought into contact, and a more gradual effect in terms of the contact area between the electrode 406 and variable resistance layer 407 is made as the force of the pressing membrane 404 changes

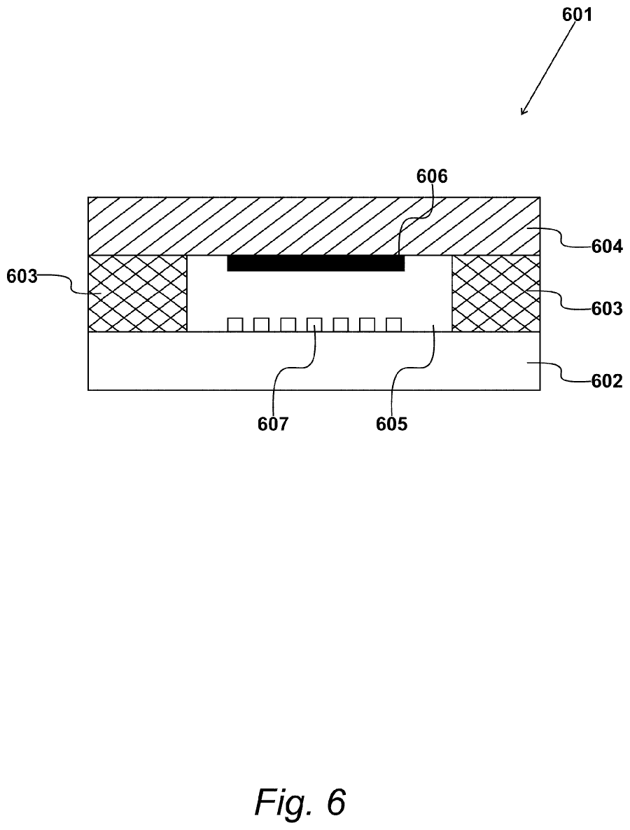

### FIG. 6

A further alternative embodiment of a pressure module in accordance with the invention is shown in FIG. 6.

In the embodiment, pressure module 601 comprises a substrate 602, a support structure 603 and a pressing membrane 604. Support structure 603 is connected to and between substrate 602 and pressing membrane 604.

Pressure module 601 is substantially similar to pressure module 201 in that an accommodating cavity 605 is formed between pressing membrane 604 and substrate 602, and, within accommodating cavity 605, an electrode 606 and a variable resistance layer 607 are respectively disposed on the surfaces of pressing membrane 604 and substrate 602 opposite to each other.

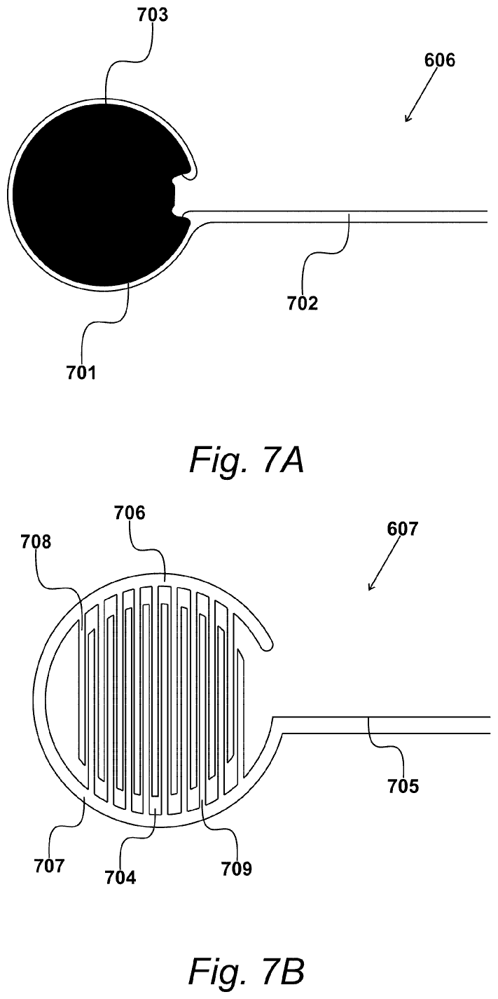

In the embodiment, electrode 606 comprises a solid circular-shaped coating, and variable resistance layer 607 comprises a coating comprising a plurality of interdigitated fingers, as will be described further with respect to FIGS. 7A and 7B.

### FIG. 7A and FIG. 7B

FIG. 7A illustrates a plan view of electrode 606 and FIG. 7B illustrates a plan view of variable resistance layer 607.

Referring to electrode 606 in FIG. 7A, electrode 606 comprises a solid circular-shaped coating 701. In the embodiment, solid circular-shaped coating 701 comprises a signal bus 702 and one end of the signal bus 702 is formed by bending into a circle 703. In the embodiment, circle 703 is coated with an electrode coating, for example, such as a metallic coating such as one comprising a silver paste or similar, to form electrode 606.

Referring to variable resistance layer 607 in FIG. 7B, variable resistance layer 607 comprises a coating comprising a plurality of interdigitated fingers 704. In the embodiment, the coating comprising a plurality of interdigitated fingers 704 comprises a signal bus 705 and one end of the signal bus 705 is formed by bending to form two opposite half-arcs 706 and 707. Each half-arc 706 and 707 extends towards the opposite half-arc 706 and 707 and comprises a plurality of signal branch lines 708 and 709 which are alternately arranged in sequence.

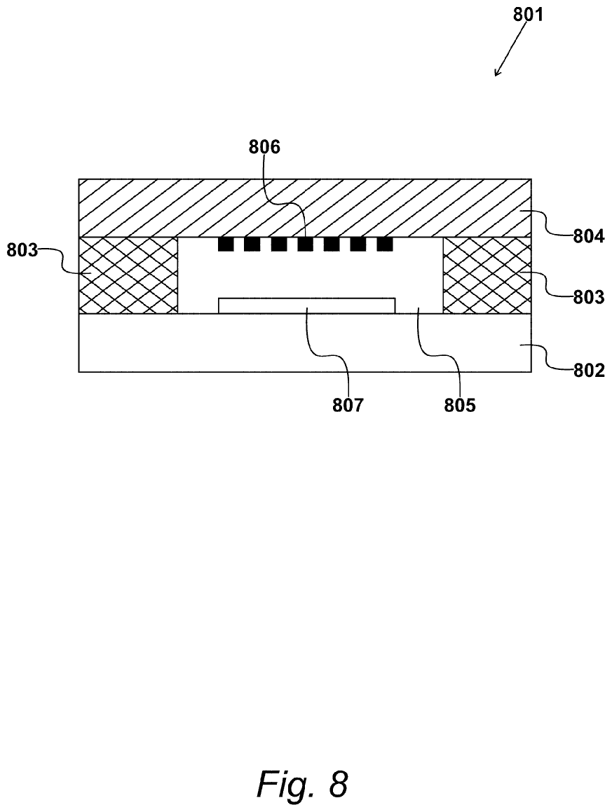

### FIG. 8

A still further embodiment of a pressure module in accordance with the invention is shown in FIG. 8.

In the embodiment, pressure module 801 comprises a substrate 802, a support structure 803 and a pressing membrane 804. Support structure 803 is connected to and between substrate 802 and pressing membrane 804.

Pressure module 801 is substantially similar to pressure module 201 in that an accommodating cavity 805 is formed between pressing membrane 804 and substrate 802, and, within accommodating cavity 805, an electrode 806 and a variable resistance layer 807 are respectively disposed on the surfaces of pressing membrane 804 and substrate 802 opposite to each other.

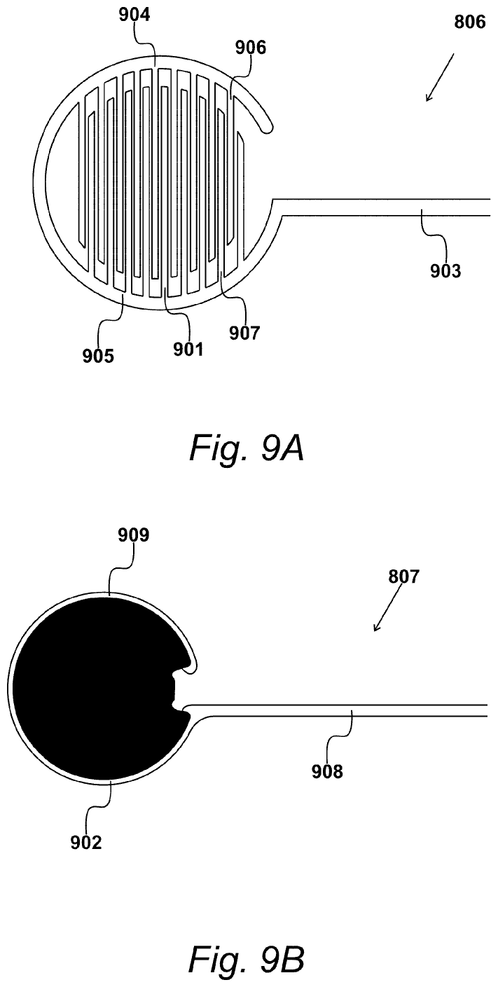

In the embodiment, electrode 806 comprises a coating comprising a plurality of interdigitated fingers, and variable resistance layer 807 comprises a solid circular-shaped coating, as will be described further with respect to FIGS. 9A and 9B.

### FIG. 9A and FIG. 9B

FIG. 9A illustrates a plan view of electrode 806 and FIG. 9B illustrates a plan view of variable resistance layer 807.

In the embodiment, electrode 806 comprises a coating comprising a plurality of interdigitated fingers 901, and variable resistance layer 807 comprises a solid circular-shaped coating 902.

Referring to electrode 806 in FIG. 9A, electrode 806 comprises a coating comprising a plurality of interdigitated fingers 901. In the embodiment, the coating comprising a plurality of interdigitated fingers 901 comprises a signal bus 903 and one end of the signal bus 903 is formed by bending to form two opposite half-arcs 904 and 905. Each half-arc 904 and 905 extends towards the opposite half-arc 905 and 904 and comprises a plurality of signal branch lines 906 and 907 which are alternately arranged in sequence.

Referring to variable resistance layer 807 in FIG. 9B, variable resistance layer 807 comprises a solid circular-shaped coating 902. In the embodiment, solid circular-shaped coating 902 comprises a signal bus 908 and one end of the signal bus 908 is formed by bending into a circle 909.

In the embodiments of FIGS. 6 and 8, one of the electrodes and the variable resistance layer is provided as a coating comprising a plurality of interdigitated fingers, and the other is a solid circular-shaped coating. In this arrangement, when the coating comprising a plurality of interdigitated fingers and solid circular-shaped coating are brought into contact, the coating comprising a plurality of interdigitated fingers is connected to the solid circular-shaped coating which enables the same function to be performed as that described in respect of the embodiment of FIG. 2, 3 or 4, with less material, which in turn allows for a lower cost pressure module design.

1. A pressure module comprising:
a substrate;
a support structure; and
a pressing membrane; wherein
said support structure is connected to said substrate and said pressing membrane to form an accommodating cavity between said substrate and said pressing membrane;
an electrode is disposed on a surface of said substrate or said pressing membrane and a variable resistance layer is respectively disposed on an opposite surface of the other of said substrate or said pressing membrane; wherein
on application of pressure to said pressing membrane, said pressing membrane is elastically deformed and said variable resistance layer is brought into contact with said electrode to form a contact area and a resistance value between said variable resistance layer and said electrode; and
said contact area and said elastic deformation is positively correlated.

2. The pressure module of claim 1, wherein said contact area is inversely related to said resistance value between said variable resistance layer and said electrode.

3. The pressure module of claim 1, wherein said electrode is disposed on said surface of said pressing membrane and said variable resistance layer is disposed on said opposite surface of said substrate; said application of pressure moves said pressing membrane onto said opposite surface of said substrate.

4. The pressure module of claim 1, wherein said electrode is disposed on said surface of said substrate and said variable resistance layer is disposed on said opposite surface of said pressing membrane; said application of pressure moves said pressing membrane onto said surface of said substrate.

5. The pressure module of 1, wherein at least one of said electrode or said variable resistance layer comprises a solid circular-shaped coating.

6. The pressure module of claim 5, wherein the other of said electrode or said variable resistance layer comprises a coating comprising a plurality of interdigitated fingers.

7. The pressure module of claim 5, wherein the other of said electrode or said variable resistance layer also comprises said solid circular-shaped coating.

8. The pressure module of claim 5, wherein said solid circular-shaped coating comprises a signal bus, one end of said signal bus is bent to form a circle, and said at least one of said electrode or said variable resistance layer are coated in the circle.

9. The pressure module of claim 6, wherein said coating comprising a plurality of interdigitated fingers comprises a signal bus, one end of said signal bus is bent to form two opposite half-arcs, and each said half-arc extends toward the opposite half-arc; further comprising a plurality of signal branch lines, said plurality of signal branch lines of said two opposite half-arcs are arranged alternately in sequence.

10. The pressure module of claim 1, wherein said substrate and said pressing membrane each comprise an insulating material.

11. A keyboard comprising the pressure module according to claim 1.

12. A pressure sensor comprising the pressure module according to claim 1.
